(19) United States
(12) Patent Application Publication
(10) Pub. No.: US 2015/0245540 A1
(43) Pub. Date: Aug. 27, 2015

(54) AIR CONDITIONING CONTROL SYSTEM AND AIR CONDITIONING CONTROL METHOD

(71) Applicant: FUJITSU LIMITED, Kawasaki-shi (JP)

(72) Inventors: Masatoshi OGAWA, Isehara (JP); Hiroshi ENDO, Isehara (JP); Hiroyuki FUKUDA, Ebina (JP); Masao KONDO, Sagamihara (JP)

(21) Appl. No.: 14/582,116

(22) Filed: Dec. 23, 2014

(30) Foreign Application Priority Data
Feb. 27, 2014 (JP) 2014-037025

(51) Int. Cl. H05K 7/20

(52) U.S. Cl. CPC H05K 7/20736

(57) ABSTRACT

A disclosed air conditioning control system includes an electronic apparatus including a heat generating component, a fan that supplies cooling air to the electronic apparatus, and a controlling unit that controls the number of rotations of the fan. The controlling unit controls the number of rotations of the fan by predicting a future temperature of the heat generating component, such that the temperature of the heat generating component lies within an allowable range, in a first case where a rate of rise in a consumed electric power of the electronic apparatus is smaller than a first threshold. In a second case where the rate of rise is equal to or larger than the first threshold, the controlling unit switches the control of the number of rotations of the fan to a control in which the number of rotations of the fan becomes larger than that in the first case.

### CROSS-REFERENCE TO RELATED APPLICATION

This application is based upon and claims the benefit of priority of the prior Japanese Patent Application No. 2014-37025, filed on Feb. 27, 2014, the entire contents of which are incorporated herein by reference.

### FIELD

The embodiment discussed herein is related to an air conditioning control system and an air conditioning control method.

### BACKGROUND

In datacenters, jobs are distributed to a plurality of electronic apparatuses such as servers, and each electronic apparatus executes its jobs. Each electronic apparatus is provided with a heat generating component such as a central processing unit (CPU). When processing a large amount of jobs, the CPU temperature rises, which may result in thermal runaway of the CPU.

To prevent such rise in CPU temperature, datacenters are provided with air conditioners to cool their electronic apparatuses. There are several types of air conditioners. For example, there is an air conditioner configured to generate the cooling air by directly taking external air around a datacenter into the datacenter and cool its electronic apparatuses with the cooling air. Also, a packaged air conditioner is sometimes used as an air conditioner, which is configured to cool the cooling air by circulating air in the datacenter and cooling the air with a heat exchanger.

Regardless of its type, the air conditioner is provided with fans to generate the cooling air. A key to reduce the electric power consumed by the datacenter lies in how to reduce the electric power consumed by these fans.

Note that technologies related to this application are disclosed in Japanese Laid-open Patent Publication Nos. 2001-284868, 05-95063, and 2011-65444.

### SUMMARY

According to one aspect discussed herein, there is provided an air conditioning control system, including an electronic apparatus including a heat generating component, a fan that supplies cooling air to the electronic apparatus, and a controlling unit that controls the number of rotations of the fan, wherein the controlling unit performs controlling the number of rotations of the fan by predicting a future temperature of the heat generating component, such that the temperature of the heat generating component lies within an allowable range, in a first case where a rate of rise in a consumed electric power of the electronic apparatus is smaller than a first threshold, and switching the control of the number of rotations of the fan to a control in which the number of rotations of the fan becomes larger than the number of rotations of the fan in the first case, in a second case where the rate of rise is equal to or larger than the first threshold.

According to another aspect discussed herein, there is provided an air conditioning control method, the method including determining, by a controlling unit that controls the number of rotations of a fan configured to supply cooling air to an electronic apparatus, whether or not a rate of rise in a consumed electric power of the electronic apparatus is equal to or larger than a first threshold, controlling, by the controlling unit, the number of rotations of the fan by predicting a future temperature of a heat generating component included in the electronic apparatus, such that the temperature of the heat generating component lies within an allowable range, in a first case where the rate of rise is determined to be smaller than the first threshold, and switching, by the controlling unit, the control of the number of rotations of the fan to a control in which the number of rotations of the fan becomes larger than the number of rotations of the fan in the first case, in a second case where the rate of rise is determined to be equal to or larger than the first threshold.

The object and advantages of the invention will be realized and attained by means of the elements and combinations particularly pointed out in the claim.

It is to be understood that both the forgoing general description and the following detailed description are exemplary and explanatory and are not restrictive of the invention.

### BRIEF DESCRIPTION OF THE DRAWINGS

FIG. 1 is a schematic top view of a datacenter according to an embodiment;

FIG. 2 is a schematic side view of the datacenter according to the present embodiment;

FIG. 3 is a hardware configuration diagram of an air conditioning control system according to the present embodiment;

FIG. 4 is a functional block diagram of a controlling unit of the air conditioning control system according to the present embodiment;

FIG. 5 is a functional block diagram of a model predicting unit of the air conditioning control system according to the present embodiment;

FIG. 6 is a flowchart illustrating an air conditioning control method according to the present embodiment;

FIGS. 7A to 7C are graphs illustrating the result of an examination according to a comparative example;

FIGS. 8A to 8C are graphs illustrating the result of an examination according to the present embodiment; and

FIG. 9 is a graph obtained by studying the amount of electric power used by a fan unit for the comparative example and the present embodiment.

### DESCRIPTION OF EMBODIMENT

Prior to describing an embodiment, matters that the inventor of this application considered will be described.

For the CPU mounted in an electronic apparatus such as a server, an upper limit temperature is set for preventing thermal runaway of the CPU. Ideally, the number of rotations of a fan for cooling the CPU is reduced as much as possible to lower the cooling performance of the fan and maintain the CPU temperature slightly lower than the upper limit temperature so that the electric power consumed by the fan can be reduced.

However, the CPU temperature always fluctuates by the availability of the server, and the CPU temperature sometimes rises abruptly. When the number of rotations of the fan is low in such a situation, the CPU temperature may exceed the upper limit temperature.

To prevent this, it is required to set a temperature sufficiently lower than the upper limit temperature as a target temperature of the CPU temperature, and increase the number of rotations of the fan such that the CPU temperature becomes the target temperature. This, however, increases the consumed electric power of the fan, and hence energy saving of the datacenter cannot be achieved.

In the following, an embodiment capable of reducing the consumed electric power of the fan will be described.

### EMBODIMENT

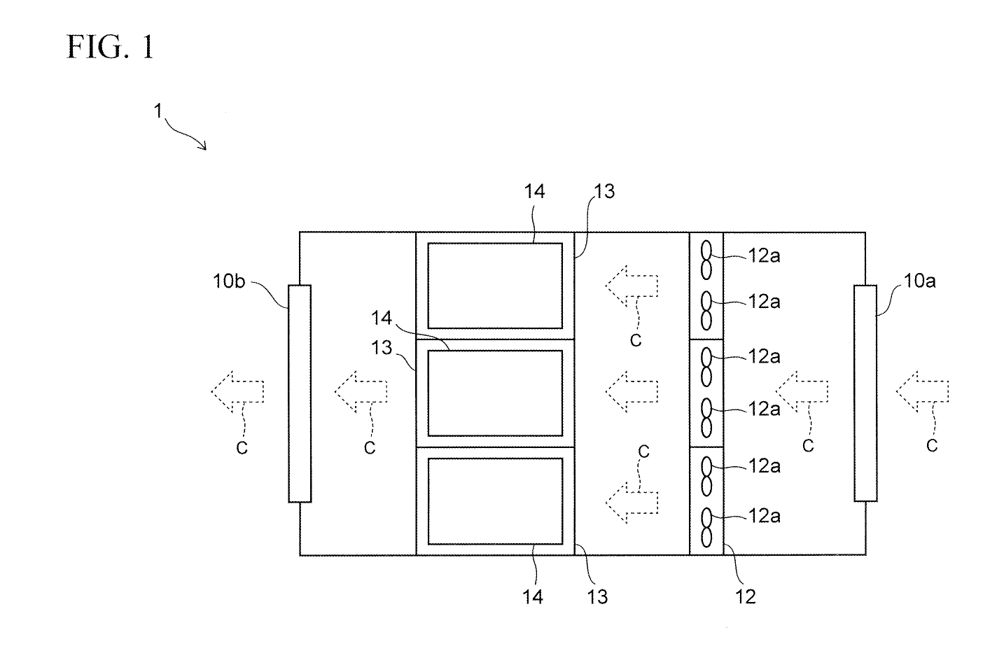

FIG. 1 is a schematic top view of a datacenter according to the present embodiment.

In the following, explanation will be described by referring to the example of a module-type datacenter, in which the electronic apparatuses such as servers are cooled by utilizing external air.

As illustrated in FIG. 1, this datacenter 1 includes a cuboidal container 10, a fan unit 12 and a plurality of racks 13 arranged in the container 10. Electronic apparatuses 14 such as servers are housed in each rack 13.

Also, of two opposite faces of the container 10, an air intake opening 10a is provided at one face, while an air exhaust opening 10b is provided at the other face.

The fan unit 12 includes a plurality of fans 12a. By rotating the fans 12a, the fans 12a take external air into the container 10 from the air intake opening 10a and generate cooling air C from the external air.

The cooling air C cools the electronic apparatuses 14 and is then discharged from the air exhaust opening 10b.

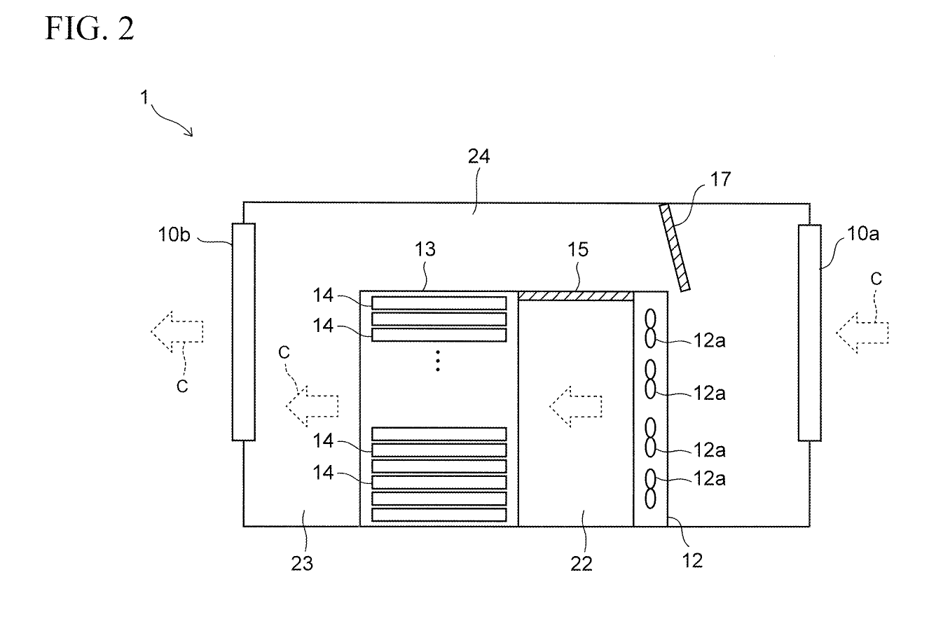

FIG. 2 is a schematic side view of the datacenter 1.

Note that the same elements in FIG. 2 as those described with reference to FIG. 1 are denoted by the same reference numerals as those in FIG. 1, and description thereof is omitted below.

As illustrated in FIG. 2, the space between the fan unit 12 and the racks 13 is served as a cold isle 22, while the space between the racks 13 and the air exhaust opening 10b is served as a hot isle 23.

A partition plate 15 is provided above the cold isle 22. Moreover, this partition plate 15, the upper faces of the racks 13, and the ceiling surface of the container 10 define a flow path 24.

A damper 17 capable of opening and closing is provided at an end of the flow path 24. When the temperature of the external air is low such as during the winter season, the damper 17 is opened, so that the warm cooling air C discharged from each electronic apparatus 14 flows through the flow path 24 and is guided to the upstream side of the fan unit 12. In this way, excessive cooling of the electronic apparatuses 14 can be prevented.

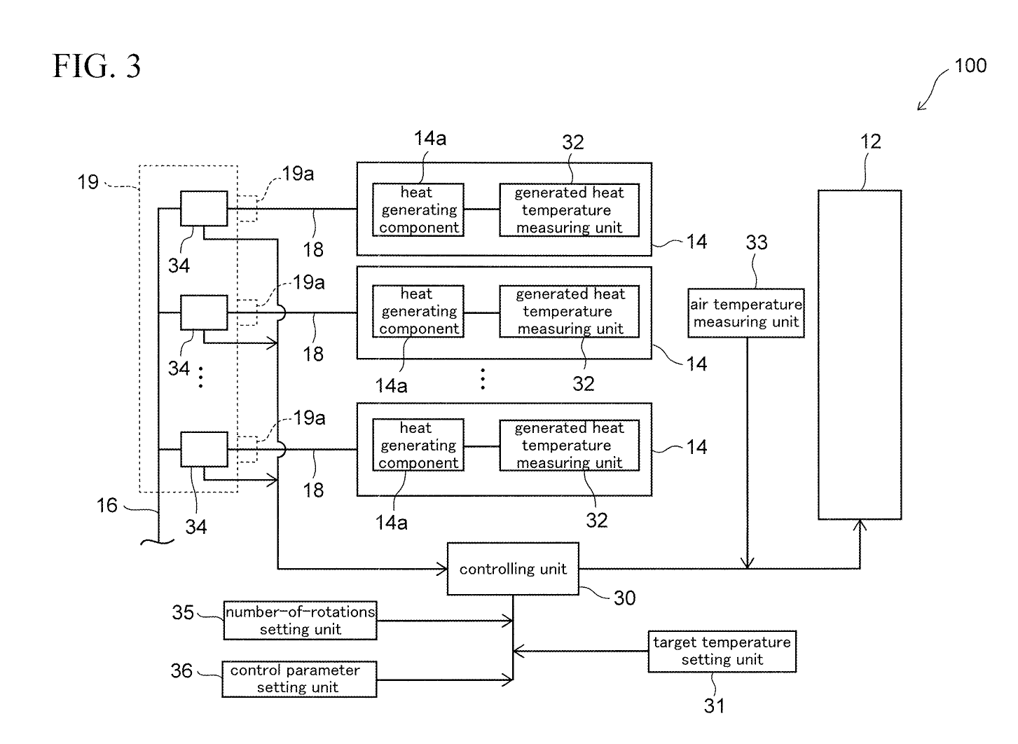

FIG. 3 is a hardware configuration diagram of an air conditioning control system for cooling the datacenter 1.

As illustrated in FIG. 3, an air conditioning control system 100 includes a power line 16, a controlling unit 30, a target temperature setting unit 31, generated heat temperature measuring units 32, an air temperature measuring unit 33, a number-of-rotations setting unit 35, and a control parameter setting unit 36.

The power line 16 is connected to a power tap 19 including a plurality of sockets 19a. An electric power is distributed to power lines 18 of the electronic apparatuses 14 from the power tap 19.

In the power tap 19, an electric power sensor 34 is provided for each power line 18. Each electric power sensor 34 is configured to measure a consumed electric power v_{P} of the corresponding electronic apparatus 14 connected to the power line 18 based on the current flowing through the power line 18 and the like, and transfer the measurement result to the controlling unit 30.

The controlling unit 30 is configured to control the number of rotations of each fan 12a of the fan unit 12. Examples of the controlling unit 30 include a microcomputer, a field programmable gate array (FPGA), and a programmable logic controller (PLC). Instead of using them, the program that the controlling unit 30 executes may be loaded onto a general-purpose computer to implement the controlling unit 30 as software.

Each electronic apparatus 14 is provided with a heat generating component 14a such a CPU. The generated heat temperature measuring unit 32 is mounted in the same chip as the heat generating component 14a, and is configured to transfer the temperature of the heat generating component 14a to the controlling unit 30 via an unillustrated communication device provided in the electronic apparatus 14. As the protocol for that transfer, the user datagram protocol (UDP) is available, for example. However, the electronic apparatus 14 and the controlling unit 30 may communicate with each other by using a different protocol.

Note that different semiconductor packages may be used for the heat generating component 14a and the generated heat temperature measuring unit 32. In this case, the heat generating component 14a and the generated heat temperature measuring unit 32 may be arranged in contact with each other to measure the temperature of the heat generating component 14a.

Moreover, in this example, the approximate consumed electric power of the heat generating component 14a can be estimated by the corresponding electric power sensor 34 of the power tap 19 as mentioned above. Therefore, there is no need to access the heat generating component 14a for the purpose of measuring the consumed electric power of the heat generating component 14a. This cannot prevent the heat generating component 14a from executing its jobs.

A temperature y₀ of each heat generating component 14a fluctuates with the air volume of the cooling air C generated by the fan unit 12. In the following, the temperature y₀ will also be called the CPU temperature y₀.

In this example, a target temperature r of the CPU temperature y₀ is determined by the target temperature setting unit 31 and, as described later, the number of rotations of each fan 12a is set such that the CPU temperature y₀ becomes close to the target temperature r.

Moreover, the air temperature measuring unit 33 is configured to measure a temperature v_{T} of the cooling air C immediately before being supplied into the electronic apparatus 14 and transfer the measurement result to the controlling unit 30.

Note that the air temperature measuring unit 33 is provided for each electronic apparatus 14, and the temperature v_{T} is measured for each electronic apparatus 14.

The number-of-rotations setting unit 35 is configured to store the maximum number of rotations u₀ of each fan 12a. This maximum number of rotations u₀ will be described later.

Moreover, the control parameter setting unit 36 is configured to store various control parameters to be used to control the number of rotations of each fan 12a.

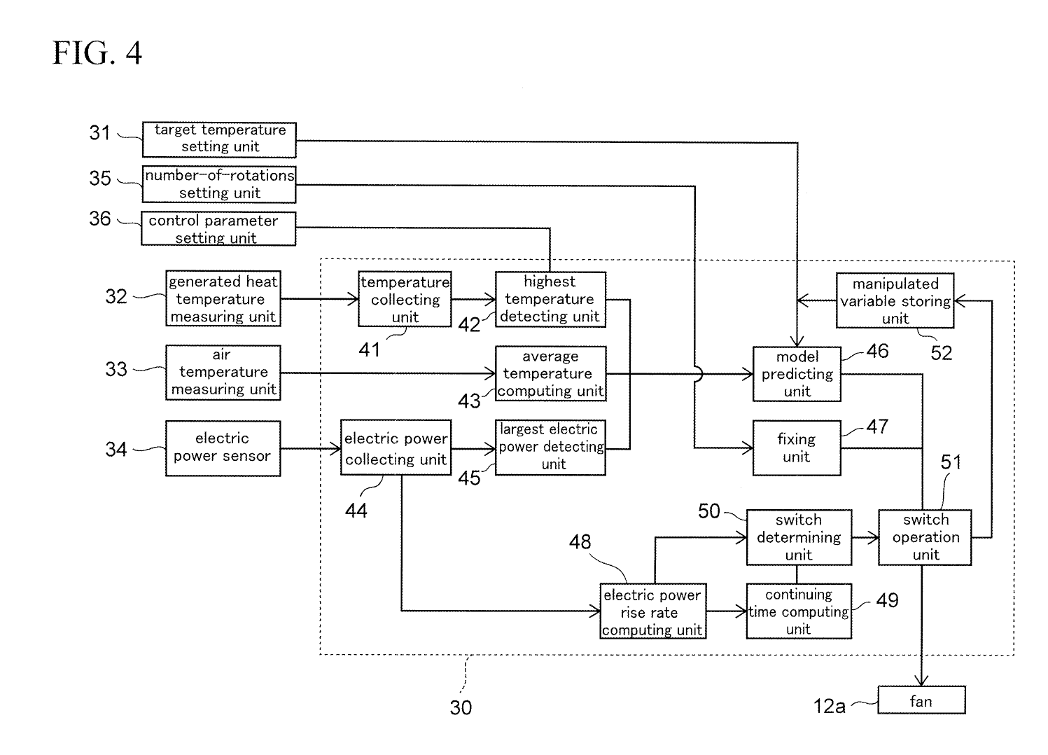

FIG. 4 is a functional block diagram of the controlling unit 30.

Note that the same elements in FIG. 4 as those described with reference to FIG. 3 are denoted by the same reference numerals as those in FIG. 3, and description thereof is omitted below.

The controlling unit 30 includes a temperature collecting unit 41, a highest temperature detecting unit 42, an average temperature computing unit 43, an electric power collecting unit 44, a largest electric power detecting unit 45, a model predicting unit 46, and fixing unit of the number of rotations 47. In addition to these, the controlling unit 30 also includes an electric power rise rate computing unit 48, a continuing time computing unit 49, a switch determining unit 50, a switch operation unit 51, and a manipulated variable storing unit 52.

The temperature collecting unit 41 is configured to collect the CPU temperatures y₀ of the heat generating components 14a measured by the generated heat temperature measuring units 32 and output them to the highest temperature detecting unit 42.

The highest temperature detecting unit 42 is configured to detect a highest temperature yᵣₑₐₗ which is the highest temperature among the plurality of CPU temperatures y₀.

On the other hand, the average temperature computing unit 43 is configured to receive the temperatures v₁ of the cooling air C at the electronic apparatuses 14 measured by the air temperature measuring units 33 and calculate an average temperature v₁ of these temperatures v_{T}.

The electric power collecting unit 44 is configured to collect the consumed electric powers v_{P} of the electronic apparatuses 14 measured by the electric power sensors 34, and output them to the largest electric power detecting unit 45 and the electric power rise rate computing unit 48.

Then, the largest electric power detecting unit 45 is configured to calculate a largest electric power v₂ which is the largest of the plurality of consumed electric powers v_{P}.

Moreover, the model predicting unit 46 is configured to calculate the number of rotations for each fan 12a with which the CPU temperatures can be within an allowable range, by predicting a future CPU temperature based on the highest temperature yᵣₑₐₗ, the average temperature v₁, and the largest electric power v₂. The method of this calculation will be described later.

On the other hand, the fixing unit 47 is configured to fix the number of rotations of each fan 12a to the maximum number of rotations u₀ of the fan 12a stored in the number-of-rotations setting unit 35 in advance.

Note that, at a given time, the number of rotations of each fan 12a is controlled by either one of the model predicting unit 46 and the fixing unit 47 in the present embodiment. Which of the model predicting unit 46 and the fixing unit 47 to be selected will be described later.

Moreover, as the maximum number of rotations u₀ mentioned above, the number of rotations larger than the number of rotations of each fan 12a under control of the model predicting unit 46 is employed.

Moreover, when the fixing unit 47 controls the number of rotations of each fan 12a, the time left for the fixing unit 47 to perform the control will be referred to as a continuing time t_{con}.

Further, the electric power rise rate computing unit 48 is configured to calculate the rate of rise in the consumed electric power v_{P} of each electronic apparatus 14. Then, the electric power rise rate computing unit 48 specifies a highest electric power rise rate vₚ_{_{—}}ₘₐₓ, which is the highest of these rise rates of v_{P}. Note that the rise rate of each consumed electric power v_{P} is defined by time differentiation of the consumed electric power v_{P}. The highest electric power rise rate vₚ_{_{—}}ₘₐₓ is outputted to the continuing time computing unit 49 and the switch determining unit 50 at the subsequent stage.

The continuing time computing unit 49 is configured to calculate the continuing time t_{con} mentioned above based on the highest electric power rise rate vₚ_{_{—}}ₘₐₓ. The method of calculating the continuing time t_{con} will be specifically described later.

The switch determining unit 50 is configured to determine which of the model predicting unit 46 and the fixing unit 47 to use to control the number of rotations of each fan 12a. The highest electric power rise rate vₚ_{_{—}}ₘₐₓ and the continuing time t_{con} are used in this determination.

The switch operation unit 51 is configured to switch the controlling agent of the number of rotations of each fan 12a to either one of the model predicting unit 46 and the fixing unit 47 based on the result of the determination by the switch determining unit 50.

Note that in the case where the model predicting unit 46 is the controlling agent of the number of rotations of each fan 12a, the switch operation unit 51 outputs a current number of rotations u of each fan 12a to the manipulated variable storing unit 52.

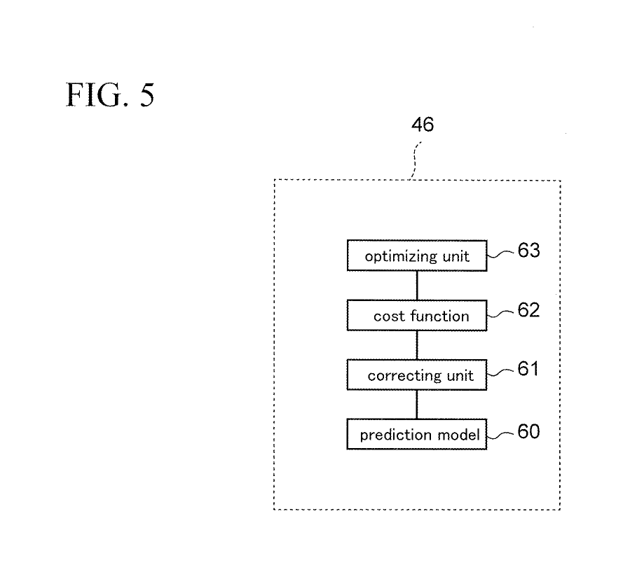

FIG. 5 is a functional block diagram of the model predicting unit 46.

As illustrated in FIG. 5, the model predicting unit 46 includes a prediction model 60, a correcting unit 61, a cost function 62, and an optimizing unit 63.

Among them, the prediction model 60 is configured to calculate a predicted value \tilde{y} of a future temperature of a heat generating component 14a based on the highest temperature yᵣₑₐₗ the average temperature v₁, the largest electric power v₂, and the number of rotations u of each fan 12a.

Moreover, the correcting unit 61 is configured to correct the predicted value \tilde{y} to bring this predicted value close to the actual temperature of the heat generating component 14a.

Further, the cost function 62 is a function which weights the difference between the predicted value \tilde{y} and the target temperature r, and its form will be described later.

Furthermore, the optimizing unit 63 is configured to calculate, in a predetermined period of time from the present to a future, a manipulated variable Δu of the fan 12a that minimizes the value J of the cost function 62 and satisfies later-described constraint conditions.

Next, an air conditioning control method according to the present embodiment will be described.

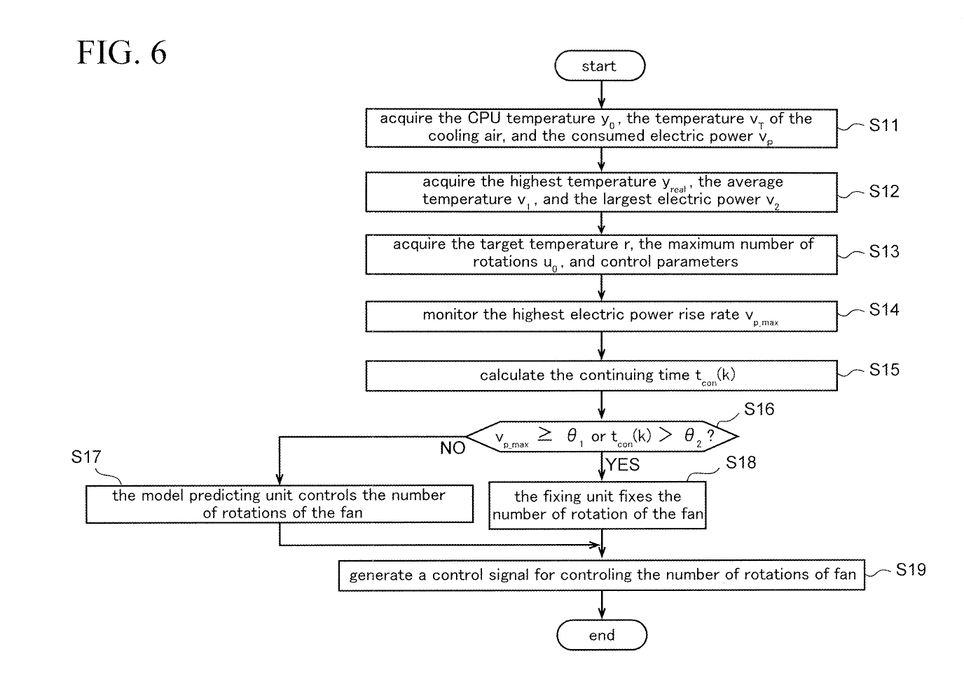

FIG. 6 is a flowchart illustrating the air conditioning control method according to the present embodiment.

This flowchart is carried out by the controlling unit 30 in a predetermined control cycle Δt. The control cycle Δt is an integer representing the cycle in which this flowchart is carried out.

First, in step S11, the controlling unit 30 acquires the CPU temperature y₀ of each heat generating component 14a, the temperature v_{T} of the cooling air C measured for each electronic apparatus 14, and the consumed electric power v_{P} of each electronic apparatus 14.

Then, the method proceeds to step S12, in which the highest temperature detecting unit 42 detects the highest temperature yᵣₑₐₗ which is the highest temperature among the plurality of CPU temperatures y₀.

At the same time, the average temperature computing unit 43 calculates the average temperature v₂ of the temperatures v_{T}.

Further, the largest electric power detecting unit 45 calculates the largest electric power v₂ which is the largest consumed electric power among the plurality of consumed electric powers v_{P}.

Then, the method proceeds to step S13.

In this step, first, the model predicting unit 46 acquires the target temperature r of the CPU temperature y₀ that is preliminarily defined in the target temperature setting unit 31.

Moreover, the fixing unit 47 acquires the maximum number of rotations u₀ of each fan 12a stored in advance in the number-of-rotations setting unit 35.

Further, the controlling unit 30 acquires various control parameters stored in the control parameter setting unit 36. Note that the contents of these control parameters will be specifically described later.

Next, in step S14, the electric power rise rate computing unit 48 calculates the rise rate of the consumed electric power v_{P} of each electronic apparatus 14, and monitors the highest electric power rise rate vₚ_{_{—}}ₘₐₓ which is the highest of these rise rates of v_{P}.

Then, the method proceeds to step S15, in which the continuing time computing unit 49 calculate the continuing time t_{con}(k) as follows.

As mentioned above, a continuing time t_{con} (k) is the time left for the fixing unit 47 to control the number of rotations of each fan 12a, and is dependent on a time point k. Note that the time point k is an integer indicating the number of times that the controlling unit 30 carries out the flowchart in FIG. 6.

First, Δt is subtracted from a continuing time t_{con}(t−1) by following the equation (1) given below:

t_{con}(k−1)=t_{con}(k−1)Δt

t_{con}(0)=0 (1).

where Δt is the control cycle mentioned above and is 1 second in this example.

The equation (1) indicates that the time left for the fixing unit 47 to perform its control is reduced by Δt each time the controlling unit 30 carries out the flowchart in FIG. 6.

Further, beside this t_{con}(k−1), t_{con}(k) is calculated by following the equation (2) given below:

$$\{ \begin{matrix}{t}_{con} ( k ) = {β}_{r} \cdot {v}_{p\_max} ( k ) & ( {θ}_{1} \leq {v}_{p\_max} ( k ) ) \\ {t}_{con} ( k ) = 0 & ( {θ}_{1} > {v}_{p\_max} ( k ) ) .\end{matrix} \qquad ( 2 )$$

As described in the formula (2), in the present embodiment, the continuing time t_{con}(k) is made proportional to the highest electric power rise rate vₚ_{_{—}}ₘₐₓ when the highest electric power rise rate vₚ_{_{—}}ₘₐₓ is equal to or higher than a first threshold θ₁. The meaning of the first threshold θ₁ will be described later. Moreover, βᵣ is a positive proportionality constant. The equation (2) is based on an idea that the higher the highest electric power rise rate vₚ_{_{—}}ₘₐₓ is, the higher the temperature of the heat generating component 14a will be, and therefore the continuing time for which the fixing unit 47 maximizes the number of rotations of each fan 12a should be made longer.

Note that the continuing time t_{con}(k) is set to 0 when the highest electric power rise rate vₚ_{_{—}}ₘₐₓ is lower than the first threshold θ₁.

Then, by following the equation (3) given below, the larger one of t_{con}(k−1) in the equation (1) and t_{con}(k) in the equation (2) is employed as the continuing time t_{con}(k) at the time point k:

t_{con}(k)=max(t_{con}(k−1),t_{con}(k)) (3).

The reason for employing the larger one of the two values t_{con} (k−1) and t_{con} (k) in this manner is for the purpose of safety. Namely, employing the larger one of the two like this makes it possible to prevent insufficient cooling of the heat generating component 14a.

Then, the method proceeds to step S16.

In step S16 and subsequent steps, one of the model predicting unit 46 and the fixing unit 47 is selected to control each fan 12a.

As mentioned above, the fixing unit 47 causes each fan 12a to rotate at the maximum number of rotations u₀. Thus, when the fixing unit 47 is selected as the controlling agent of each fan 12a, the heat generating component 14a can be cooled more proactively than when the model predicting unit 46 is selected.

For this reason, in this example, the fixing unit 47 is selected when the heat generating component 14a needs to be proactively cooled, and the model predicting unit 46 is selected otherwise.

Moreover, one of the highest electric power rise rate vₚ_{_{—}}ₘₐₓ and the continuing time t_{con}(k) is employed as criterion to determine which one of the two is to be selected.

When the highest electric power rise rate vₚ_{_{—}}ₘₐₓ rises abruptly, it is very likely that the temperature of the heat generating component 14a will rise in a future. Thus, the highest electric power rise rate vₚ_{_{—}}ₘₐₓ can serve as criterion to determine whether or not to proactively cool the heat generating component 14a.

Moreover, the continuing time t_{con}(k) is proportional to the highest electric power rise rate vₚ_{_{—}}ₘₐₓ as described in the equation (2). Therefore, like the highest electric power rise rate vₚ_{_{—}}ₘₐₓ, the continuing time t_{con}(k) can also serve as criterion to determine whether or not to proactively cool the heat generating component 14a.

For the above reason, in step S16, the switch determining unit 50 determines whether or not the highest electric power rise rate vₚ_{_{—}}ₘₐₓ is equal to or larger than the first threshold θ₁ (vₚ_{_{—}}ₘₐₓ≧θ₁). Also, the switch determining unit 50 determines whether or not the continuing time t_{con}(k) is larger than a second threshold θ₂ (t_{con}(k)>θ₂).

The thresholds θ₁ and θ₂ are criteria to determine whether or not the highest electric power rise rate vₚ_{_{—}}ₘₐₓ and the continuing time t_{con}(k) are so large that the heat generating component 14a must be cooled proactively. The thresholds θ₁ and θ₂ may be found in advance through tests or simulations.

Here, when either conditions vₚ_{_{—}}ₘₐₓ≧θ₁ or t_{con}(k)>θ₂ is fulfilled, the method proceeds to step S18. On the other hand, when both of the two conditions are not fulfilled, the method proceeds to step S17.

First, the case where the method proceeds to step S17 will be described.

In step S17, the model predicting unit 46 controls the number of rotations of each fan 12a by predicting a future temperature of the heat generating component 14a, such that the temperature of the heat generating component 14a can be within an allowable range. This control is performed by using a prediction model as follows.

The general equation of this prediction model is described as the equation (4) given below:

\tilde{y}(k+1)=f(u(k),v₁(k),v₂(k)) (4).

\tilde{y}(k+1) in the left-hand side of the equation (4) is a predicted value of the temperature of the heat generating component 14a at a time point k+1.

Moreover, u(k) in the right-hand side of the equation (4) is the number of rotations of each fan 12a at the time point k, whereas v₁(k) is the average temperature of the cooling air C at the time point k. Then, v₂(k) is the largest electric power among the consumed electric powers of the electronic apparatuses 14 at the time point k.

Note that as the number of rotations u(k), the one stored in the manipulated variable storing unit 52 is used.

In the present embodiment, the generation equation (4) is specialized as the equations (5) and (6) given below:

x(k+1)=Ax(k)+Bᵤu(k)+Bᵥv(k) (5)

\tilde{y}(k)=C·x(k) (6).

Here,

$$v ( k ) = ( \begin{matrix}{v}_{1} ( k ) \\ {v}_{2} ( k )\end{matrix} ) . \qquad ( 7 )$$

x(k) in the equations (5) and (6) is a state variable at the time point k and is a n-dimensional (n is a natural number) vector. Moreover, A is an n×n matrix, Bᵤ is an n-dimensional vector, Bᵥ is an n×2-dimensional matrix, and C is an n-dimensional vector.

Note that the values of the components in A, Bᵤ, Bᵥ, and C can be found through system identification based on test data such that the predicted value \tilde{y} of the future temperature of the heat generating component 14a can be best approximated. As the method of the system identification, a prediction error method or a subspace identification method is available.

Moreover, when it is possible to derive a differential equation of a physical model which expresses the dynamic characteristics of the temperature of the heat generating component 14a, the values of the components in A, Bᵤ, Bᵥ, and C can be found by linearizing the differential equation through the Taylor expansion.

Further, it is known that n is determined by an order n_{d} of the model and a dead time dₜ, and is expressed as n=n_{d}+dₜ. The reason for this will be explained in a later-described reference example.

Note that the dead time dₜ is a dead time of the number of rotations of each fan 12a, and is defined as the time taken for the fan 12a to reach a certain number of rotations after the fan 12a receives an instruction for this number of rotations. In this example, this time is rounded off to make the dead time dₜ an integer value. For example, dₜ=12 seconds.

Meanwhile, although a state-space model is used in the above case, the model may be expressed as a multiple regression model or data such as a map function.

Then, the correcting unit 61 corrects the predicted value \tilde{y}(k+1) of the temperature of the heat generating component 14a at the time point k+1 based on the equation (8) given below to calculate a corrected predicted value y(k+1|k):

y(k+1|k)=+1|k)+(yᵣₑₐₗ(k)−y(k|k−1)) (8).

In the equation (8) and the subsequent equations, when a variable α at a time point p is to be calculated from information at a time point q, the variable α will be described as α(p|q).

The first term of the right-hand side of the equation (9), \tilde{y}(k+1|k), is the uncorrected predicted value of the temperature of the heat generating component 14a at the time point k+1.

Moreover, the second term of the right-hand side of the equation (8) is a correction term. yᵣₑₐₗ (k) appearing in that correction term is the real highest temperature among the heat generating components 14a at the time point k and is the value acquired in step S12. Also, y(k|k−1) in the correction term is the predicted value of the temperature of the heat generating component 14a at the time point k. At the time point k, the real value is deviated from the predicted value by yᵣₑₐₗ (k)−y(k|k−1). Therefore, by adding yᵣₑₐₗ(k)−y(k|k−1) to the right-hand side of the equation (8), it is possible to prevent the predicated value at the time point k+1 from deviating from the real value.

Here, a future period p is introduced. The future period p is an integer indicating a period of time from the present to a future at which the temperature of the heat generating component 14a is to be predicted. In the following, the future period p is 100, for example.

Moreover, the change amount Δu of the number of rotations of the fan 12a is defined by the equation (9) given below:

u(k+i|k)=u(k+i−1|k)+Δu(k+i|k)

(i=0, 1, . . . , p−1) (9).

In the equation (9), i is an index which equally divides the future period p into p parts.

As can be understood from the equation (9), a change amount Δu(k+i|k) is defined by a number of rotations u(k+i|k) of the fan 12a at a time point k+i, and a number of rotations u(k+i−1|k) of the fan 12a at a time point k+i−1, which is the antecedent time point of k+i by one step.

Moreover, as each number of rotations u(k) in the equation (9), those stored in the manipulated variable storing unit 52 can be used.

Note that since the number of rotations of the fan 12a is manipulated by the controlling unit 30, the change amount Δu will also be called the manipulated variable Δu in the following.

By using the index i in the equation (9), the equations (5), (6), and (8) can be expressed as the equations (10) to (12) given below, respectively:

x(k+i+1|k)=Ax(k+i|k)+Bᵤu(k+i|k)+Bᵥv(k|k) (10)

\tilde{y}(k+i+1|k)=C·x(k+i+1|k) (11)

y(k+i+1|k)=\tilde{y}(k+i+1|k)+(yᵣₑₐₗ(k)−y(k|k−1)) (12).

Further, the allowable ranges of the parameters are defined as follows:

yₘᵢₙ≦y(k+i+1|k)≦yₘₐₓ (13).

Δuₘᵢₙ≦Δu(k+i|k)≦Δuₘₐₓ (14)

uₘᵢₙ≦u(k+i|k)≦uₘₐₓ (15).

The equation (13) defines the allowable range of the highest temperature y of the heat generating component 14a, where yₘᵢₙ and yₘₐₓ represent the lower limit temperature and upper limit temperature of the allowable range, respectively. These values are not particularly limited. As the upper limit temperature yₘₐₓ, a temperature of about 80° C., at which thermal runaway of the heat generating component 14a does not occur, can be employed. Moreover, the lower limit temperature yₘᵢₙ is 20° C., for example.

The equation (14) defines the allowable range of the manipulated variable Δu of the fan 12a. A minimum value Δuₘᵢₙ and a maximum value Δuₘₐₓ of the allowable range are limit values within which the number of rotations of the fan 12a can be changed in one manipulation.

Moreover, the equation (15) defines the allowable range of the number of rotations u of the fan 12a, where Uₘᵢₙ and Uₘₐₓ represent the lower limit value and upper limit value of the allowable range, respectively.

The parameters y, Δu, and u are subjected to the constraint conditions of the equations (13) to (15), respectively.

Moreover, in the present embodiment, besides the above constraint conditions, the equation (16) given below is provided as another constraint condition on the manipulated variable Δu:

Δu(k+h|k)=0

(h=m, . . . , p−1) (16).

The equation (16) indicates that the manipulated variable Δu becomes 0 at and after a time point k+m. This is based on an idea that the manipulated variable Δu should gradually approach 0 toward the end of the future period, instead of shifting the manipulated variable Δu suddenly to 0 at the end.

Meanwhile, the value of m is not particularly limited. In this example, m is 1.

Then, the optimizing unit 63 calls the cost function 62 which is described as the equation (17) given below:

$$J ( k ) = {\sum }_{i = 0}^{p - 1} [ y ( k + i + 1 \vert k ) - r ( k + i + 1 ) ] Q [ y ( k + i + 1 \vert k ) - r ( k + i + 1 ) ] + Δ u ( k + i \vert k ) {R}_{Δ u} ( k + i \vert k ) + [ u ( k + i \vert k ) - {u}_{target} ( k + i ) ] {R}_{u} [ u ( k + i \vert k ) - {u}_{target} ( k + i ) ] . \qquad ( 17 )$$

In the equation (17), Q, RΔᵤ, and Rᵤ are scalars representing weights. The first term of the right-hand side of the equation (17) represents an operation to bring the temperature y of the heat generating component 14a, which is a control target, close to the target temperature r, and Q is a weight for this operation, i.e. a target value following parameter.

The second term of the right-hand side of the equation (17) represents an operation to bring the change amount Δu of the number of rotations u close to 0, and RΔᵤ is a weight for this operation, i.e. a manipulated variable reducing parameter. The smaller the RΔᵤ, the larger the manipulated variable Δu, and the larger the RΔᵤ, the smaller the manipulated variable Δu.

The third term of the right-hand side of the equation (17) represents an operation to bring the number of rotations u close to a target number of rotations u_{target}. Since the consumed electric power of the fan 12a can be reduced when the target number of rotations u_{target} is smaller, u_{target} is set to 0 in the present embodiment. On the other hand, Rᵤ is a weight for the operation to bring the number of rotations close to the target number of rotations u_{target}, i.e. a manipulated variable shift width parameter.

These control parameters Q, RΔ_{E}, and Rᵤ are stored in the control parameter setting unit 36 mentioned above, and are acquired by the model predicting unit 46 through the highest temperature detecting unit 42.

Then, the optimizing unit 63 calculates an input sequence of the manipulated variable Δu which minimizes the value J of the cost function 62, based on the equation (18) given below:

$$\{ Δ {u}_{opt} ( k \vert k ) , … , Δ {u}_{opt} ( m - 1 + k \vert k ) \} = arg {min}_{Δ u ( k \vert k ) , … , Δ u ( m - 1 + k \vert k )} J ( k ) . \qquad ( 18 )$$

Then, the optimizing unit 63 extracts the first element Δuₒₚₜ(k|k) in the optimum input sequence {Δuₒₚₜ(k|k), . . . , Δuₒₚₜ(m−1+k|k)} calculated from the equation (18).

Further, the optimizing unit 63 calculates the number of rotations u(k) of the fan 12a at the time point k from the equation (19) given below:

u(k)=u(k−1)+Δuₒₚₜ(k|k) (19).

The optimizing solver which minimizes the cost function 62 may use a metaheuristic numerical solution which searches for an approximate solution such as an genetic algorithm (GA) or particle swarm optimization (PSO). Note that sequential quadratic programming (SQP) is used in this example to solve a quadratic programming problem.

By the above operation, step S17 ends.

Thereafter, the method proceeds to step S19, in which the controlling unit 30 generates a control signal for controlling the number of rotations of each fan 12a, and changes the number of rotations of the fan 12a to u(k) in the equation (19).

Next, the case where the method proceeds from step S16 to step S18 will be described.

In step S18, each fan 12a is rotated at the maximum number of rotations u₀ stored in the number-of-rotations setting unit 35 under control of the fixing unit 47.

The maximum number of rotations u₀ is not particularly limited, as long as it is greater than the number of rotations of each fan 12a under control of the model predicting unit 46 in step S17, and can be set to any suitable number based on simulations and tests using the actual system.

In such a test, the temperature v₁ of the cooling air C is set to the highest temperature allowable for the specifications of the electronic apparatuses 14. Then, the air volume of each fan 12a is set to the largest possible air volume that the fan 12a can produce. Under this state, the number of rotations of the fan 12a is gradually lowered, while the highest temperature y of the CPUs is monitored. Then, once a maximum number of rotations is found at which the highest temperature y does not exceed the upper limit value yₘₐₓ mentioned above, that number of rotations can be determined as the maximum number of rotations u₀.

Note that as step S18 is kept being performed in this manner, the continuing time t_{con}(k) decreases gradually. Therefore, as the flowchart in FIG. 6 is repeatedly executed, the condition t_{con}(k)>θ₂ in step S16 will not eventually be fulfilled, and hence step S17 is performed again. The time, which takes to restart step S17 after step S18 is started when the highest electric power rise rate vₚ_{_{—}}ₘₐₓ reaches or exceeds the first threshold θ₁, will be referred to as a predetermined time T.

According to this, after step S18 is started when the highest electric power rise rate vₚ_{_{—}}ₘₐₓ reaches or exceeds the first threshold θ₁, step S18 is continuously performed, thereby setting the number of rotations of each fan 12a to the maximum number of rotations u₀, until the predetermined time T elapses.

Then, once the predetermined time T elapses, step S17 is performed again.

Note that the longer the continuing time t_{con}(k) the longer the fixing unit 47 controls the number of rotations of the fan 12a. Therefore, as the continuing time t_{con}(k) becomes longer, the predetermined time T becomes longer as well. In the present embodiment, as described in the equation (2), the continuing time t_{con}(k) is made proportional to the highest electric power rise rate vₚ_{_{—}}ₘₐₓ. Thus, the predetermined time T is set to be longer in accordance with the highest electric power rise rate vₚ_{_{—}}ₘₐₓ.

Moreover, the highest electric power rise rate vₚ_{_{—}}ₘₐₓ used in step S16 to determine whether or not vₚ_{_{—}}ₘₐₓ≧θ₁ is fulfilled, is acquired in step S14 before step S16. Thus, the highest electric power rise rate vₚ_{_{—}}ₘₐₓ used to set the predetermined time T has the value of the highest electric power rise rate vₚ_{_{—}}ₘₐₓ at the time when the highest electric power rise rate vₚ_{_{—}}ₘₐₓ reaches or exceeds the first threshold θ₁.

After that, the method proceeds to step S19 mentioned above, in which the controlling unit 30 generates a control signal for controlling the number of rotations of the fan 12a and fixes the number of rotations of the fan 12a to the maximum number of rotations u₀.

Note that each fan 12a may be rotated at a larger number of rotations than the maximum number of rotations u₀ without fixing the number of rotations as described above.

By the above operation, the basic steps of the air conditioning control method according to the present embodiment end.

According to the present embodiment described above, the number of rotations of each fan 12a is fixed to the maximum number of rotations u₀ in steps S18 and S19 when it is determined in step S16 that the highest electric power rise rate vₚ_{_{—}}ₘₐₓ is equal to or greater than the first threshold θ₁ (vₚ_{_{—}}ₘₐₓ≧θ₁).

When the consumed electric power of an electronic apparatus 14 increases, it is likely that the temperature of its heat generating component 14a will rise in the future. Therefore, by using the rise rate of the electric power as a criterion for determination in this manner, it is possible to change the number of rotations of each fan 12a to the maximum number of rotations u₀ without waiting until the temperature of the heat generating component 14a actually rises, and thereby prevent the timing to fix the number of rotations of the fan 12a to the maximum number of rotations u₀ from being delayed with respect to the rise in the temperature of the heat generating component 14a.

To confirm this advantage, the inventors of the present application conducted the following examination.

In this examination, how the highest temperature y among the plurality of CPU temperatures changed with time was studied for a comparative example and the present embodiment.

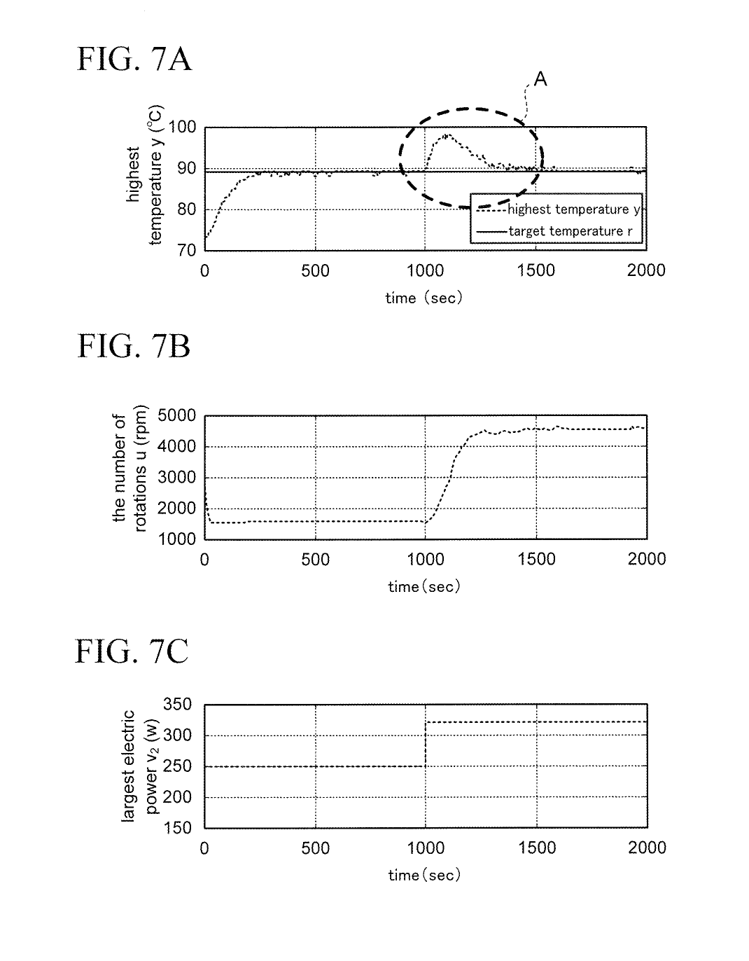

FIG. 7A illustrates the result of this examination on the comparative example.

In this comparative example, the fixing unit 47 in FIG. 4 was not provided, and the model predicting unit 46 controlled the number of rotation of the fan 12a all the time. Note that the target temperature r of the CPU was set to 89° C.

Moreover, FIG. 7B is a graph illustrating changes in the number of rotations u of the fan 12a with time, and FIG. 7C is a graph illustrating changes in the largest electric power v₂ with time.

As illustrated in a dotted circle A in FIG. 7A, in the comparative example, overshoot occurred in which the highest temperature y exceeded the target temperature r when the utilization of the heat generating component 14a rose and the largest electric power v₂ abruptly increased.

In order to prevent the highest temperature y from exceeding the target temperature r even when overshoot occurs, the target temperature r needs to be set lower than 89° C. For instance, in this example, the temperature rises by about 10° C. by overshoot, and therefore the target temperature r must be set to about 79° C., which is 10° C. lower than 89° C.

However, when the target temperature r is lowered in this manner, it is necessary to constantly maintain the number of rotations of the fan 12a high to prevent the highest temperature y from exceeding the target temperature r, which results in an increase in the consumed electric power of the fan 12a.

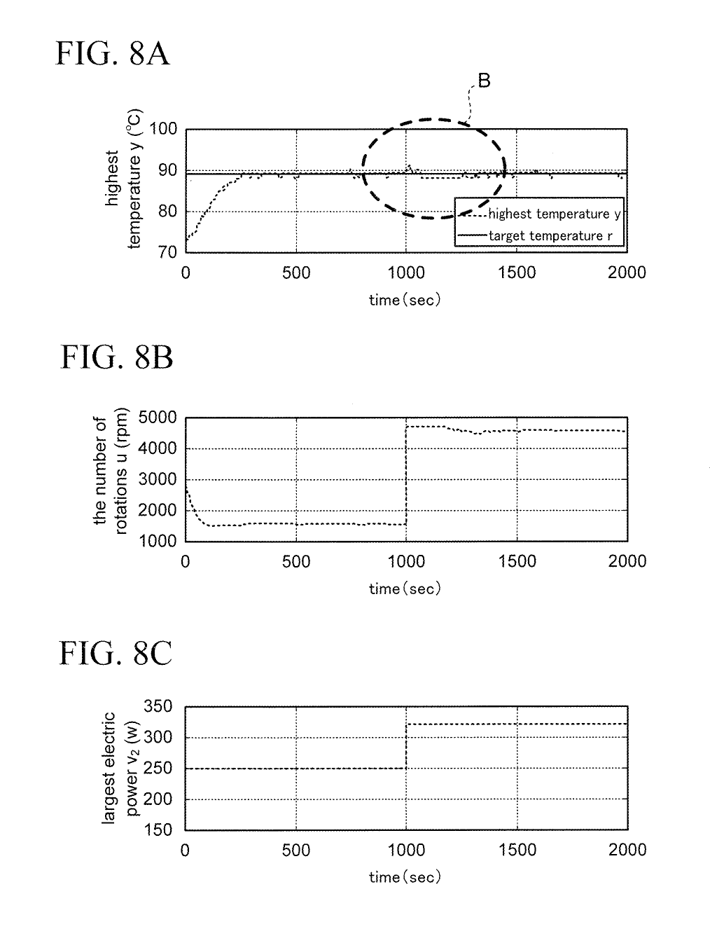

On the other hand, FIGS. 8A to 8C are graphs obtained by conducting the same examination on the present embodiment.

Among these graphs, FIG. 8A is a graph illustrating changes in the highest temperature y among the CPU temperatures with time.

Moreover, FIG. 8B is a graph illustrating changes in the number of rotations u of the fan 12a with time, and FIG. 8C is a graph illustrating changes in the largest electric power v₂ with time.

As illustrated in a dotted circle B in FIG. 8A, in the present embodiment, even when the largest electric power v₂ abruptly increased, the highest temperature y was maintained at or below the target temperature r for most of the period, and noticeable overshoot like the one in the comparative example did not occur.

This is considered because the controlling agent of the fan 12a was switched from the model predicting unit 46 to the fixing unit 47 at a time point of 1000 seconds at which the largest electric power v₂ increased abruptly, and hence the fan 12a was rotated at the maximum number of rotations u₀ under control of the fixing unit 47.

In the present embodiment, since overshoot hardly occurs as described above, it is not necessary to set the target temperature r to a low temperature in anticipation of the overshoot. Accordingly, the consumed electric power of the fan 12a can be reduced than that in the comparative example.

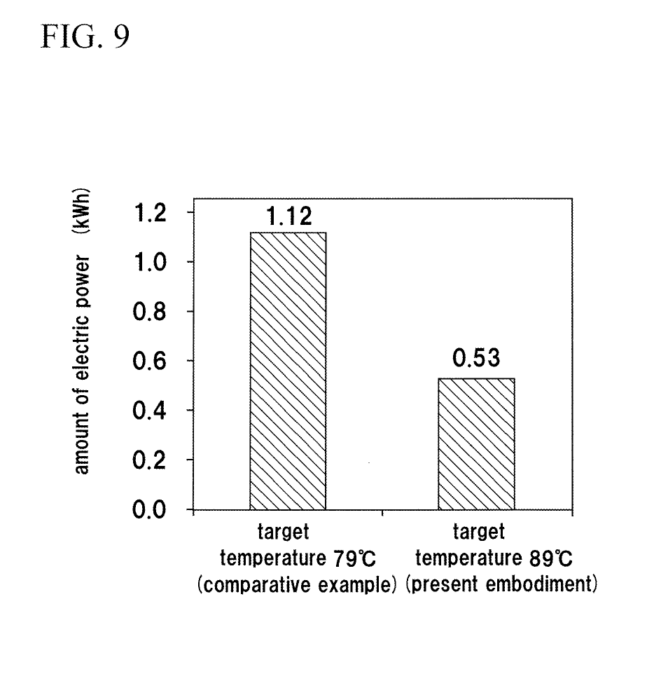

FIG. 9 is a graph obtained by studying the amount of electric power consumed by the fan unit 12 for the comparative example in FIGS. 7A to 7C and the present embodiment in FIGS. 8A to 8C.

As described above, the target temperature r in the comparative example was set to 79° C. On the other hand, the target temperature r in the present embodiment was set to 89° C.

As illustrated in FIG. 9, the amount of electric power consumed by the fan unit 12 in the present embodiment can be reduced than that in the comparative example by approximately 52%. This is because the target temperature r does not need to be lowered in the present embodiment, and therefore the number of rotations of each fan 12a does not need to be increased as mentioned above.

From the results in FIGS. 7A to 7C, FIGS. 8A to 8C, and FIG. 9, it was confirmed that using the highest electric power rise rate vₚ_{_{—}}ₘₐₓ as a criterion to determine whether or not to set the number of rotations of each fan 12a to the maximum number of rotations u₀ as in the present embodiment, is effective in reducing the consumed electric power of the fan 12a.

Although the present embodiment is described above in detail, the present embodiment is not limited to the above.

For example, although FIG. 1 exemplarily illustrates the module-type datacenter 1 configured to generate cooling air C from external air, an evaporative cooler may be provided to the module-type datacenter 1, and the temperature and humidity of the cooling air C may be adjusted by using the evaporative cooler.

Further, instead of a module-type datacenter, the present embodiment may be applied to a datacenter configured to generate cooling air C with a packaged air conditioner, and the number of rotations of the fan of the packaged air conditioner may be controlled.

Furthermore, instead of the air conditioning of a datacenter, the present embodiment may be applied to the air conditioning of a facility including many heat generating parts.

### Reference Example

In step S17 of the present embodiment described above, it is mentioned that the dimension n of the state variable x(k), the order n_{d} of the model, and the dead time dₜ satisfy the relation n=n_{d}+dₜ. The reason for this will be described below.

First, consider the state-space model of discrete time represented by the following equation (20). Note that the number of the input parameter and the output parameter of this model is one, and dimension of this model is one.

$$x ( k + 1 ) = Ax ( k ) + Bu ( k ) \\ y ( k ) = Cx ( k ) \\ A = [ a ] \\ B = [ b ] \\ C = [ c ] \\ x ( 0 ) = {x}_{1} ( 0 ) \qquad ( 20 )$$

Here, in the case where the dead time of an input u is 1 second and the cycle of k is 1 second, the model can be expressed such that, like the equation (21) given below, the value of the input u is stored in the second component of the state variable and shifted to the first row in the next cycle.

$$x ( k + 1 ) = Ax ( k ) + Bu ( k ) \\ y ( k ) = Cx ( k ) \\ x ( 0 ) = [ \begin{matrix}{x}_{1} ( 0 ) \\ 0\end{matrix} ] , \\ A = [ \begin{matrix}a & b \\ 0 & 0\end{matrix} ] , \\ B = [ \begin{matrix}0 \\ 1\end{matrix} ] , \\ C = [ c ] . \qquad ( 21 )$$

In the example of the equation (21), the order of the state variable is 2, which is the sum of 1 as the model order and 1 as a value taking into consideration of the dead time.

Moreover, in the case where the dead time of the input u is 2 seconds, the model can be expressed such that, like the equation (22) given below, the second component and the third component of the state variable and the value of the input u are shifted, as in the above case.

$$x ( k + 1 ) = Ax ( k ) + Bu ( k ) \\ y ( k ) = Cx ( k ) \\ x ( 0 ) = [ \begin{matrix}{x}_{1} ( 0 ) \\ \begin{matrix}0 \\ 0\end{matrix}\end{matrix} ] , \\ A = [ \begin{matrix}a & 0 & b \\ 0 & 0 & 0 \\ 0 & 1 & 0\end{matrix} ] , \\ B = [ \begin{matrix}0 \\ \begin{matrix}1 \\ 0\end{matrix}\end{matrix} ] , \\ C = [ \begin{matrix}c & 0 & 0\end{matrix} ] \qquad ( 22 )$$

In the example of the equation (22), the order of the state variable is 3, which is the sum of 1 as the model order and 2 as a value taking into consideration the dead time.

In the case where the dead time of the input u is 3 seconds, the model can be expressed such that, like the equation (23) given below, the second component, the third component, and the fourth component of the state variable and the value of the input u are shifted, as in the above cases.

$$x ( k + 1 ) = Ax ( k ) + Bu ( k ) \\ y ( k ) = Cx ( k ) \\ x ( 0 ) = [ \begin{matrix}{x}_{1} ( 0 ) \\ \begin{matrix}0 \\ \begin{matrix}0 \\ 0\end{matrix}\end{matrix}\end{matrix} ] , \\ A = [ \begin{matrix}a & 0 & 0 & b \\ 0 & 0 & 0 & 0 \\ 0 & 1 & 0 & 0 \\ 0 & 0 & 1 & 0\end{matrix} ] , \\ B = [ \begin{matrix}0 \\ \begin{matrix}1 \\ \begin{matrix}0 \\ 0\end{matrix}\end{matrix}\end{matrix} ] , \\ C = [ \begin{matrix}c & 0 & \begin{matrix}0 & 0\end{matrix}\end{matrix} ] \qquad ( 23 )$$

In the example of the equation (23), the order of the state variable is 4, which is the sum of 1 as the model order and 3 as a value taking into consideration the dead time.

Next, consider the state-space model of discrete time represented by the following equation (24). Note that the number of the input parameter and the output parameter of this model is one, and dimension of this model is two.

$$x ( k + 1 ) = Ax ( k ) + Bu ( k ) \\ y ( k ) = Cx ( k ) \\ A = [ \begin{matrix}{a}_{11} & {a}_{12} \\ {a}_{21} & {a}_{22}\end{matrix} ] \\ B = [ \begin{matrix}{b}_{1} \\ {b}_{2}\end{matrix} ] \\ C = [ \begin{matrix}{c}_{1} & {c}_{2}\end{matrix} ] \\ x ( 0 ) = [ \begin{matrix}{x}_{1} ( 0 ) \\ {x}_{2} ( 0 )\end{matrix} ] \qquad ( 24 )$$

Here, in the case where the dead time of the input u is 1 second and the cycle of k is 1 second, the model can be expressed such that, like the equation (25) given below, the value of the input u is stored in the third component of the state variable and shifted to the first row and the second row in the next cycle.

$$x ( k + 1 ) = Ax ( k ) + Bu ( k ) \\ y ( k ) = Cx ( k ) \\ x ( 0 ) = [ \begin{matrix}{x}_{1} ( 0 ) \\ {x}_{2} ( 0 ) \\ 0\end{matrix} ] , \\ A = [ \begin{matrix}{a}_{11} & {a}_{12} & {b}_{1} \\ {a}_{21} & {a}_{22} & {b}_{2} \\ 0 & 0 & 0\end{matrix} ] , \\ B = [ \begin{matrix}0 \\ 0 \\ 1\end{matrix} ] , \\ C = [ \begin{matrix}{c}_{1} & {c}_{2} & 0\end{matrix} ] \qquad ( 25 )$$

Thus, the order of the state variable is 3, which is the sum of 2 as the model order and 1 as a value taking into consideration the dead time.

Moreover, in the case where the dead time of the input u is 2 seconds and the cycle of k is 1 second, the model can be expressed such that, like the equation (26) given below, the value of the input u is stored in the third component of the state variable, and further stored in the fourth component in the next cycle and then shifted to the first row and the second row.

$$x ( k + 1 ) = Ax ( k ) + Bu ( k ) \\ y ( k ) = Cx ( k ) \\ x ( 0 ) = [ \begin{matrix}{x}_{1} ( 0 ) \\ \begin{matrix}{x}_{2} ( 0 ) \\ \begin{matrix}0 \\ 0\end{matrix}\end{matrix}\end{matrix} ] , \\ A = [ \begin{matrix}{a}_{11} & {a}_{12} & 0 & {b}_{1} \\ {a}_{21} & {a}_{22} & 0 & {b}_{2} \\ 0 & 0 & 0 & 0 \\ 0 & 0 & 1 & 0\end{matrix} ] , \\ B = [ \begin{matrix}0 \\ \begin{matrix}0 \\ \begin{matrix}1 \\ 0\end{matrix}\end{matrix}\end{matrix} ] , \\ C = [ \begin{matrix}{c}_{1} & {c}_{2 } & \begin{matrix}0 & 0\end{matrix}\end{matrix} ] \qquad ( 26 )$$

In the example of the equation (26), the order of the state variable is 4, which is the sum of 2 as the model order, and 2 as a value taking into consideration the dead time.

Thus, the relation n=n_{d}+dₜ is fulfilled.

All examples and conditional language provided herein are intended for the pedagogical purpose of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention has been described in detail, it should be understood that the various changes, substitutions, and alterations could be made hereto without departing from the spirit and scope of the invention.

What is claimed is:

1. An air conditioning control system, comprising:
an electronic apparatus including a heat generating component;
a fan that supplies cooling air to the electronic apparatus; and
a controlling unit that controls the number of rotations of the fan, wherein
the controlling unit performs:
controlling the number of rotations of the fan by predicting a future temperature of the heat generating component, such that the temperature of the heat generating component lies within an allowable range, in a first case where a rate of rise in a consumed electric power of the electronic apparatus is smaller than a first threshold; and
switching the control of the number of rotations of the fan to a control in which the number of rotations of the fan becomes larger than the number of rotations of the fan in the first case, in a second case where the rate of rise is equal to or larger than the first threshold.

2. The air conditioning control system according to claim 1, wherein the controlling unit performs:
controlling the number of rotations of the fan such that the number of rotations of the fan becomes larger than the number of rotations of the fan in the first case, until a predetermined time elapses after the rate of rise becomes equal to or larger than the first threshold; and
switching the control of the number of rotations of the fan after the elapse of the predetermined time to the control in which the number of rotations of the fan is controlled by predicting the future temperature of the heat generating component, such that the temperature of the heat generating component lies within the allowable range.

3. The air conditioning control system according to claim 2, wherein the predetermined time is set to be longer in accordance with the rate of rise at the time when the rate of rise becomes equal to or larger than the first threshold.

4. The air conditioning control system according to claim 1, further comprising:
a power line that supplies an electric power to the electronic apparatus; and
an electric power sensor connected to the power line, the electric power sensor measuring the consumed electric power, wherein
the controlling unit calculates the rate of rise from the consumed electric power measured by the electric power sensor.

5. The air conditioning control system according to claim 1, wherein
a plurality of the electronic apparatuses are provided, and
the controlling unit employs a largest electric power, which is the largest of consumed electric powers among the plurality of electronic apparatuses, as the consumed electric power of the electronic apparatus.

6. The air conditioning control system according to claim 1, further comprising a predicting unit that predicts the future temperature of the heat generating component based on a temperature of the heating generating component, a temperature of the cooling air immediately before entering the electronic apparatus, and an electric power consumed by the electronic apparatus.

7. The air conditioning control system according to claim 1, further comprising the fixing unit of the number of the rotations, the fixing unit fixing the number of rotations of the fan to a larger number of rotations than the number of rotations in the first case.

8. An air conditioning control method, the method comprising:
determining, by a controlling unit that controls the number of rotations of a fan configured to supply cooling air to an electronic apparatus, whether or not a rate of rise in a consumed electric power of the electronic apparatus is equal to or larger than a first threshold;
controlling, by the controlling unit, the number of rotations of the fan by predicting a future temperature of a heat generating component included in the electronic apparatus, such that the temperature of the heat generating component lies within an allowable range, in a first case where the rate of rise is determined to be smaller than the first threshold; and
switching, by the controlling unit, the control of the number of rotations of the fan to a control in which the number of rotations of the fan becomes larger than the number of rotations of the fan in the first case, in a second case where the rate of rise is determined to be equal to or larger than the first threshold.

9. The air conditioning control method according to claim 8, further comprising:
controlling, by the controlling unit, the number of rotations of the fan such that the number of rotations of the fan becomes larger than the number of rotations of the fan in the first case, until a predetermined time elapses after the rate of rise becomes equal to or larger than the first threshold; and
switching, by the controlling unit, the control of the number of rotations of the fan after the elapse of the predetermined time to a control in which the number of rotations of the fan is controlled by predicting the future temperature of the heat generating component, such that the temperature of the heat generating component lies within the allowable range.

10. The air conditioning control method according to claim 8, wherein, in the determining whether or not the rate of rise in the consumed electric power is equal to or larger than the first threshold, the consumed electric power is acquired by using an electric power sensor connected to a power line that supplies an electric power to the electronic apparatus, and the rate of rise is calculated from the consumed electric power.
